(19) United States
(12) Patent Application Publication
(10) Pub. No.: US 2025/0140647 A1
(43) Pub. Date: May 1, 2025

(54) SEMICONDUCTOR PACKAGE AND FORMATION METHOD THEREOF

(71) Applicant: Taiwan Semiconductor Manufacturing Company, Ltd., Hsinchu (TW)

(72) Inventors: Jhih-Yu Wang, New Taipei City (TW); Po-Han Wang, Hsinchu City (TW); Yu-Hsiang Hu, Hsinchu City (TW); Hung-Jui Kuo, Hsinchu City (TW)

(73) Assignee: Taiwan Semiconductor Manufacturing Company, Ltd., Hsinchu (TW)

(21) Appl. No.: 18/494,748

(22) Filed: Oct. 25, 2023

(51) Int. Cl. H01L 23/48; H01L 23/00; H01L 23/538; H01L 23/544; H01L 25/10

(52) U.S. Cl. CPC H01L 23/481; H01L 23/5383; H01L 23/544; H01L 24/03; H01L 24/05; H01L 25/105; H01L 2223/54426; H01L 2224/0346; H01L 2224/05546

(57) ABSTRACT

A semiconductor package and a formation method thereof are provided. The method includes: providing a device wafer, with a barrier layer covering a back surface of a semiconductor substrate, and having a through substrate via (TSV) penetrating through the barrier layer and extending into the semiconductor substrate; defining an alignment mark over the back surface of the semiconductor substrate; forming a seed layer over the back surface of the semiconductor substrate, wherein the seed layer has a recess portion corresponding to the alignment mark; forming a mask layer on the seed layer; performing a lithography process by using a redefined alignment mark formed by the recess portion of the seed layer, to form an opening through the mask layer and overlapping the TSV; filling a conductive structure in the opening; removing the mask layer and portions of the seed layer around the conductive structure; and singulating the processed device wafer.

### BACKGROUND

In recent decades, semiconductor industry has experienced rapid growth due to continuous improvements in integration density. For the most part, these improvements have come from continuous reduction in minimum feature size, which allows more components to be integrated into a given area. Nevertheless, these integration improvements are essentially two-dimensional (2D) in nature, in that the area occupied by the integrated components is essentially on the surface of the semiconductor wafer. As demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for forming backside contact features on a back side of a semiconductor die (in wafer form), according to some embodiments of the present disclosure.

FIG. 2A through FIG. 2H are schematic cross-sectional views illustrating intermediate structures at various stages during the process flow shown in FIG. 1.

FIG. 3 is a schematic plan view illustrating an arrangement of alignment marks and through substrate vias (TSVs) and possible shapes of the alignment marks, according to some embodiments of the present disclosure.

FIG. 4 is a schematic cross-sectional view illustrating a semiconductor package including a device die singulated from the device wafer shown in FIG. 2H, according to some embodiments of the present disclosure.

FIG. 5 is a flow diagram illustrating a method for forming the semiconductor package shown in FIG. 4, according to some embodiments of the present disclosure.

FIG. 6A through FIG. 6F are schematic cross-sectional views illustrating intermediate structures at various stages during the process shown in FIG. 5.

FIG. 7 is a flow diagram illustrating a method for forming backside contact features on a back side of a semiconductor die (in wafer form), according to some embodiments of the present disclosure.

FIG. 8A through FIG. 8I are schematic cross-sectional views illustrating intermediate structures at various stages during the process flow shown in FIG. 7.

FIG. 9 is a schematic cross-sectional view illustrating a semiconductor package including a device die singulated from the device wafer shown in FIG. 8I, according to some embodiments of the present disclosure.

FIG. 10A is a schematic cross-sectional view illustrating a device die, according to some embodiments of the present disclosure.

FIG. 10B is a schematic cross-sectional view illustrating a device die, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a three-dimensional semiconductor package in which a semiconductor die is formed with through substrate vias (TSVs) for establishing routing paths from a front side to a back side of the semiconductor die. The TSVs extend to backside contact features disposed at the back side of the semiconductor die, and can be connected to another package component via the backside contact features. Overlay of the backside contact features on the TSVs should be sufficient, to ensure low resistance along the routing paths. Typically, a patterning process for forming the backside contact features is performed by using the TSVs as alignment marks. However, as dimension (e.g., diameter) of the TSVs has been significantly reduced, the TSVs are no longer visible while being observed by an exposure tool. A more promising alignment method is required for forming the backside contact features.

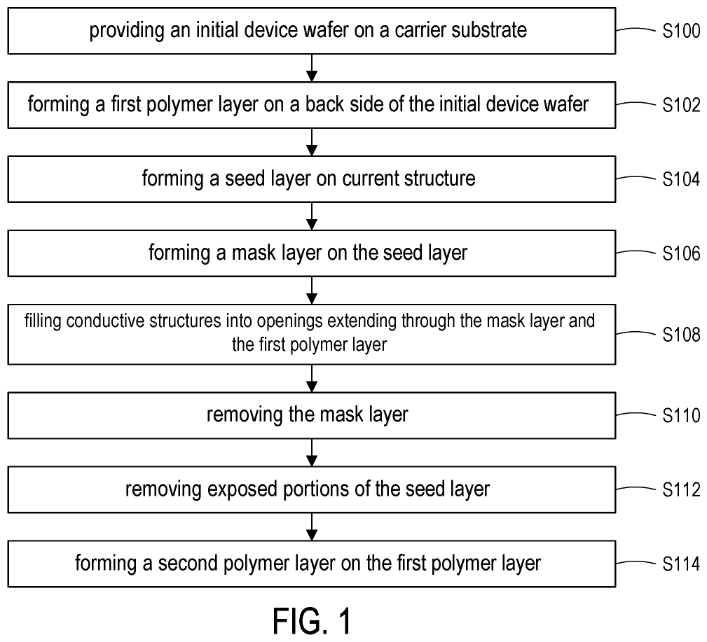

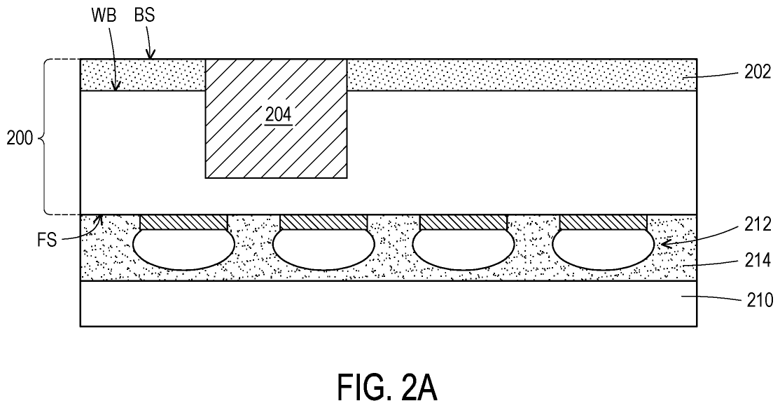

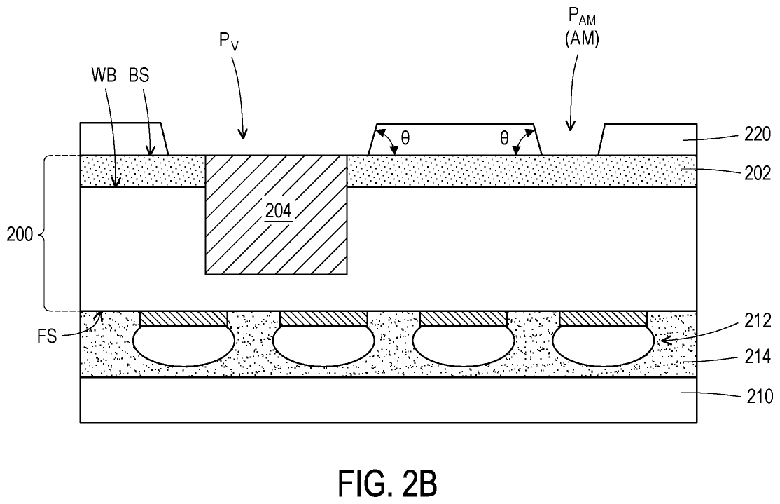

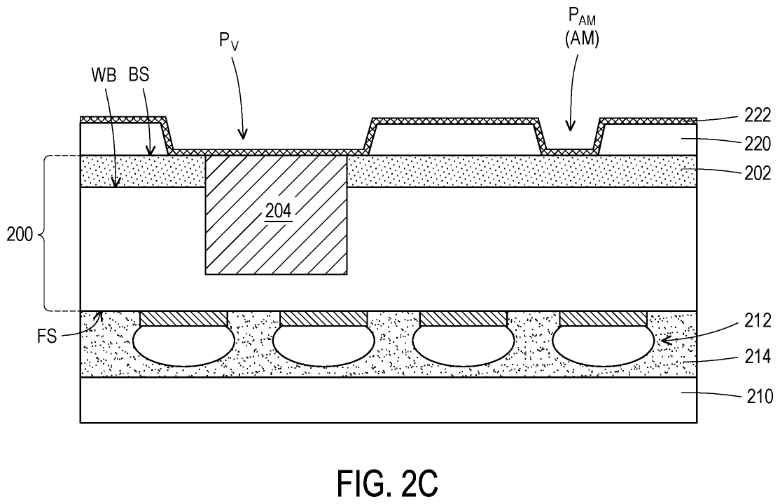

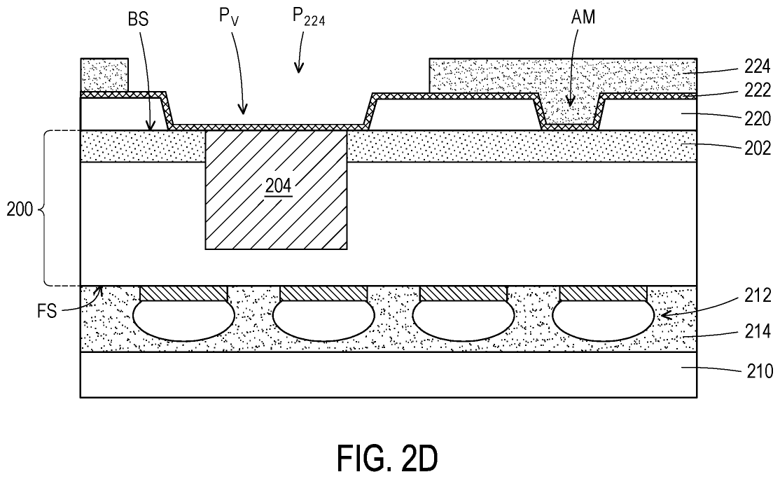

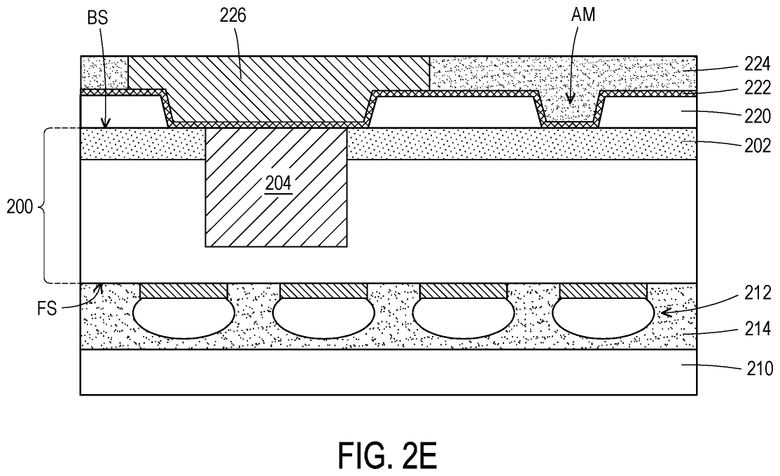

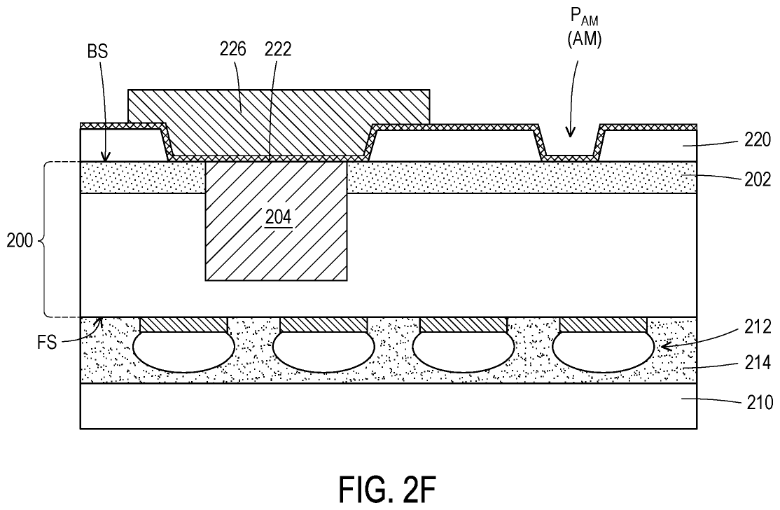

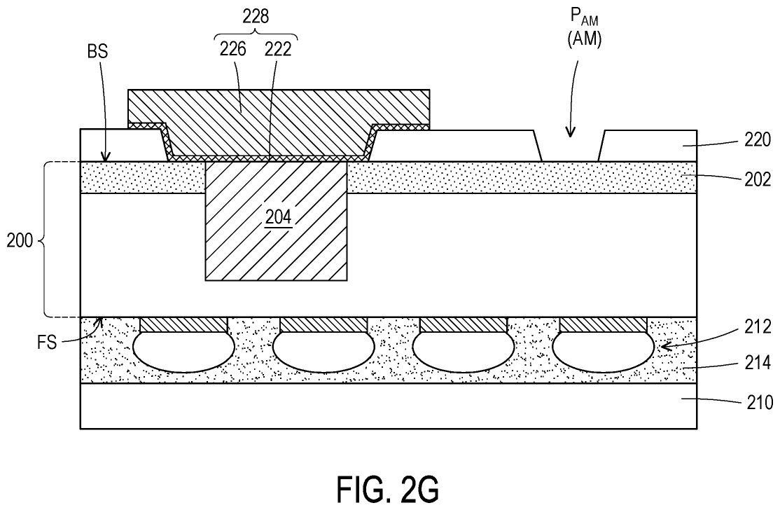

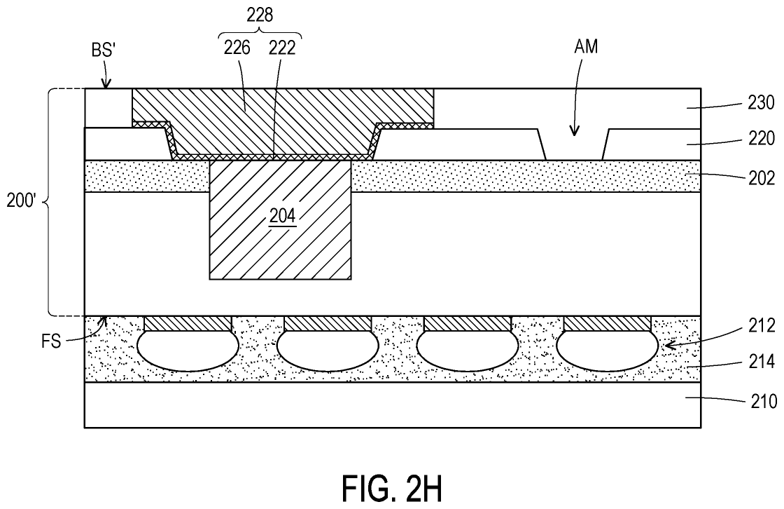

FIG. 1 is a flow diagram illustrating a method for forming backside contact features on a back side of a semiconductor die (in wafer form), according to some embodiments of the present disclosure. FIG. 2A through FIG. 2H are schematic cross-sectional views illustrating intermediate structures at various stages during the process flow shown in FIG. 1.

Referring to FIG. 1 and FIG. 2A, at a step S100, an initial device wafer 200 is provided on a carrier substrate 210. Although not respectively depicted, the initial device wafer 200 includes a semiconductor substrate with active devices formed on its front surface, and includes dielectric layers stacked over the active devices. Conductive features spread in the dielectric layers interconnect the active devices, and rout the interconnected active devices to a front side FS of the initial device wafer 200. The carrier substrate 210 is attached to the front side FS of the initial device wafer 200. In some embodiments, the carrier substrate 210 is attached to the front side FS of the initial device wafer 200 through electrical connectors 212. In these embodiments, the electrical connectors 212 may be encapsulated by an adhesive 214 filled in between the front side FS of the initial device wafer 200 and the barrier substrate 210.

Further, the initial device wafer 200 includes a barrier layer 202 along a back surface WB of the semiconductor substrate, and includes TSVs 204 (only a single one is shown) penetrating through the barrier layer 202 and extending into the semiconductor substrate. In some embodiments, terminal surfaces of the TSVs 204 may be substantially coplanar with a top surface of the barrier layer 202, and the terminal surfaces of the TSVs 204 as well as the top surface of the barrier layer 202 collectively define a back side BS of the initial device wafer 200. An insulating material, such as silicon nitride, may be used for forming the barrier layer 204. In addition, the barrier layer 204 may be formed to a thickness less than 5 μm. As an example, the thickness of the barrier layer 204 may be about 2 μm.

Referring to FIG. 1 and FIG. 2B, at a step S102, a polymer layer 220 is formed on the back side BS of the initial device wafer 200. Openings P_{V} (only a single one is shown) in the polymer layer 220 overlap and expose the TSVs 204. In addition, openings P_{AM} (only a single one is shown) in the polymer layer 220 define alignment marks AM to be used in a subsequent lithography process. In some embodiments, the polymer layer 220 is formed of a photosensitive polymer material, and the openings P_{V}, P_{AM} are formed by performing a lithography process on the polymer layer 220. In these embodiments, the openings P_{V}, P_{AM} may be formed with slanted sidewalls. For instance, an angle θ defined between the sidewalls of the openings P_{V}, P_{AM} and the top surface of the barrier layer 202 may be less than 90°, and greater than or equal to 75°. In addition, the polymer layer 220 may be formed to a thickness ranging from 3 μm to 20 μm.

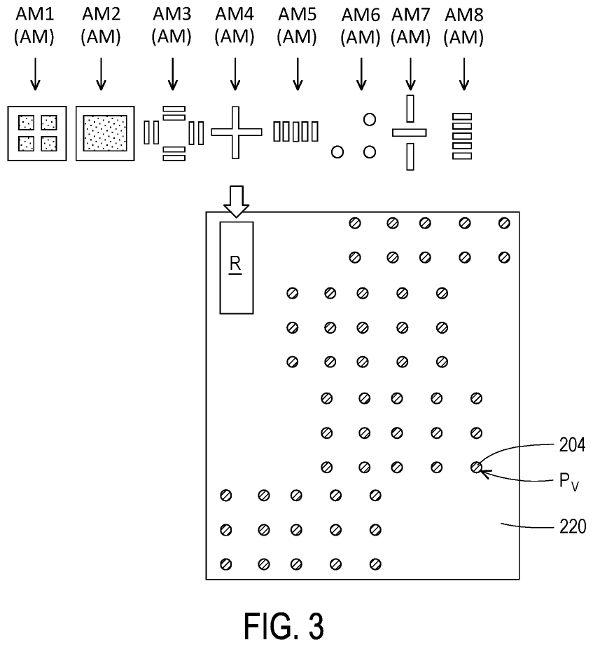

FIG. 3 is a schematic plan view illustrating an arrangement of the openings P_{V}, P_{AM} and possible shapes of the openings P_{AM}, according to some embodiments of the present disclosure.

Referring to FIG. 3, a plurality of the openings P_{AM} may be arranged within a region R aside an array of the openings P_{V}. Groups of the openings P_{AM} respectively define an alignment mark AM, such as (but not limited to) one of the listed alignment marks AM1, AM2, AM3, AM4, AM5, AM6, AM7 and AM8. There may be a single alignment mark AM or a group of identical or different alignment marks AM (e.g., two or three identical or different alignment marks AM) defined within the region R. Each alignment mark AM is greater in size as compared to each opening P_{V}. As an example, each alignment mark AM may have a total width/length ranging from 30 μm to 2000 μm, whereas each opening P_{V} may have a width (diameter) ranging from 2 μm to 6 μm. Further, the region R may be separated from the array of the openings P_{V} by a spacing greater than 100 μm.

Referring to FIG. 1 and FIG. 2C, at a step S104, a seed layer 222 is formed on the current structure. The seed layer 222 may conformally cover exposed surfaces of the polymer layer 220, the barrier layer 202 and the TSVs 204. In some embodiments, the seed layer 222 is a single layer, such as a copper layer. In other embodiments, the seed layer 222 is a multilayer structure including, for example, a titanium layer and a copper layer on top of the titanium layer.

Referring to FIG. 1 and FIG. 2D, at a step S106, a mask layer 224 is formed on the seed layer 222. The mask layer 224 may be a photoresist layer, and a lithography process may be performed on the mask layer 224 to form openings P₂₂₄ (only a single one is shown) through the mask layer 224. The openings P₂₂₄ respectively overlap one of the openings P_{V}. During the lithography process, the alignment marks AM can facilitate accurate positioning of the openings P₂₂₄. The alignment marks AM are currently covered by the seed layer 222 and the mask layer 224. Nevertheless, the conformal seed layer 222 is recessed at the alignment marks AM, and can reflect incident light through the mask layer 224. In this way, clear contrast along boundaries of the alignment marks AM is visible on an exposure tool, and can be used for accurately positioning the openings P₂₂₄.

Referring to FIG. 1 and FIG. 2E, at a step S108, conductive structures 226 (only a single one is shown) are filled into the communicated openings P₂₂₄, P_{V}. A via portion of each conductive feature 226 is filled in one of the openings P_{V} in the polymer layer 220, and a pad portion of each conductive feature 226 laterally extends over the polymer layer 220. According to some embodiments, a plating process is used for filling out the openings P₂₂₄, P_{V} with a conductive material, and a planarization process is performed to remove excessive portions of the conductive material over the mask layer 224. Portions of the conductive material in the openings P₂₂₄, P_{V} remain to form the conductive structures 226.

Referring to FIG. 1 and FIG. 2F, at a step S110, the mask layer 224 is removed. In those embodiments where the mask layer 224 is a photoresist layer, the mask layer 224 may be removed by performing a stripping process or an ashing process. Upon removal of the mask layer 224, portions of the seed layer 222 not shielded by the conductive structures 226 are exposed.

Referring to FIG. 1 and FIG. 2G, at a step S112, the exposed portions of the seed layer 226 are removed. Remained portions of the seed layer 222 and the overlying conductive features 226 form backside contact features 228, for connecting the TSVs 204 to external conductive features. A via portion of each backside contact feature 228 penetrates through the polymer layer 220 to reach one of the TSVs 204, whereas a pad portion of each backside contact feature 228 lying on the polymer layer 220 may engage with an external conductive feature. Further, upon patterning of the seed layer 222 portions of the polymer layer 220 around the backside contact features 228 and portions of the barrier layer 202 overlapped with the alignment marks AM are exposed.

Referring to FIG. 1 and FIG. 2H, at a step S114, a polymer layer 230 is formed around the backside contact features 228 to cover the exposed portions of the polymer layer 220 and the barrier layer 202. Currently, the openings P_{AM} for defining the alignment marks AM are filled up by the polymer layer 230. In some embodiments, top surfaces of the backside contact features 228 are substantially coplanar with a top surface of the polymer layer 230. Further, in some embodiments, the polymer layers 220, 230 are formed of the same polymer material, such as polyimide (PI), poly(p-phenylene-benzobisoxazole) (PBO), or the like. In some embodiments, as compared to the polymer layer 230, the polymer layer 220 has greater adhesivity to the material for forming the barrier layer 202. As an example, the polymer layers 220, 230 may be both formed of polyimide, but slight difference between the polyimide for forming the polymer layer 220 and the polyimide for forming the polymer layer 230 may result that the polymer layer 220 has greater adhesivity to the material for forming the barrier layer 202.

Up to here, the initial device wafer 200 has been processed to form a device wafer 200′ with the polymer layers 220, 230 and the backside contact features 228. As identical with the initial device wafer 200, the device wafer 200′ also has the front side FS deployed with the electrical connectors 212. On the other hand, the device wafer 200′ may have a back side BS' collectively defined by the top surfaces of the backside contact features 228 and the top surface of the polymer layer 230.

According to some embodiments, the device wafer 200′ is then detached from the carrier substrate 210, and subjected to a packaging process.

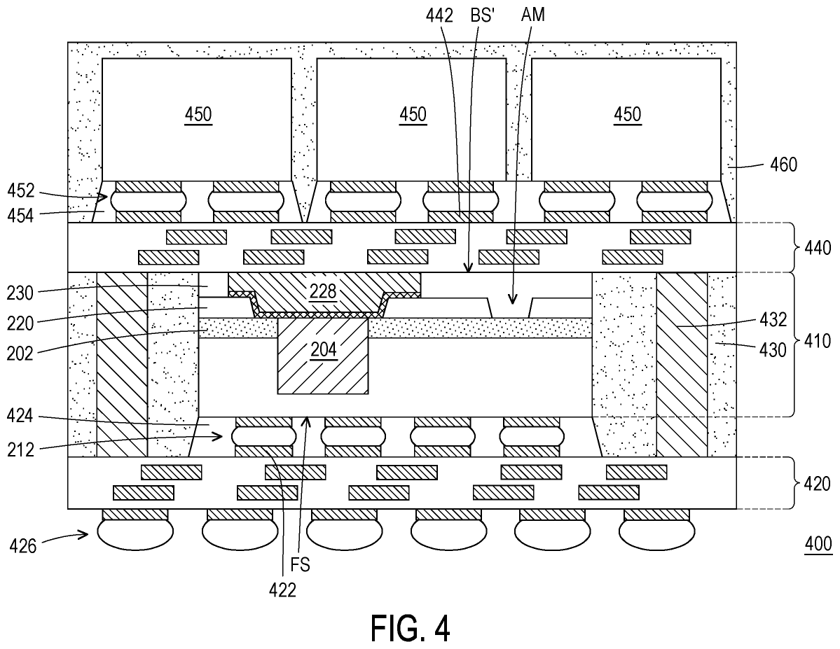

FIG. 4 is a schematic cross-sectional view illustrating a semiconductor package 400 including a device die 410 singulated from the device wafer 200′ shown in FIG. 2H, according to some embodiments of the present disclosure.

Referring to FIG. 4, the device die 410 singulated from the device wafer 200′ shown in FIG. 2H is included in the semiconductor package 400. Specifically, the device die 410 including the alignment marks AM defined in the polymer layer 220 may be attached to a frontside redistribution structure 420 via the electrical connectors 212 deployed at the front side FS of the device die 410. Conductive pads 422 exposed at a top surface of the frontside redistribution structure 420 are jointed to the electrical connectors 212, and an underfill 424 may laterally encapsulate the jointed electrical connectors 212 and conductive pads 422. Conductive features in the frontside redistribution structure 420 out-rout the jointed electrical connectors 212 and conductive pads 422 to the other side of the frontside redistribution structure 420, at which connective terminals 426 as inputs/outputs (I/Os) of the semiconductor package 400 are disposed.

An encapsulant 430 may be formed on the frontside redistribution structure 420, and laterally encapsulate the device die 410 as well as components in between the device die 410 and the frontside redistribution structure 420. Moreover, a backside redistribution structure 440 may be further formed along a top surface of the encapsulant 430 and the back side BS' of the device die 410. As similar to the frontside redistribution structure 420, the backside redistribution structure 440 may include a stack of dielectric layers and conductive feature spreading in the dielectric layers. The conductive features in the backside redistribution structure 440 out-rout the backside contact features 228 exposed at the back side BS' of the device die 410, to a top side of the backside redistribution structure 440. By further inserting the polymer layer 220 in between the polymer layer 230 exposed at the back side BS' of the device die 410 and the barrier layer 202 covering the semiconductor substrate of the device die 410, cracking of the conductive features in the backside redistribution structure 440 disposed on the back side BS' of the device die 410 can be effectively reduced, along with improvement of positioning accuracy of the backside contact features 228.

In certain cases, through insulator vias (TIVs) 432 may be disposed around the device die 410 on the frontside redistribution structure 420, and laterally encapsulated by the encapsulant 430. By disposing the TSVs 432, conductive features of the backside redistribution structure 440 can be electrically connected to the conductive features of the frontside redistribution structure 420 along the TIVs 432.

Furthermore, top device dies 450 may be attached onto the backside redistribution structure 440, and are communicative with the device die 410 through the conductive features in the backside redistribution structure 440 and the backside contact features 228 of the device die 410. Specifically, electrical connectors 452 disposed along bonding sides of the top device dies 450 are attached to conductive pads 442 exposed at a top surface of the backside redistribution structure 440. In addition, underfill(s) 454 may be disposed between the top device dies 450 and the backside redistribution structure 440, to laterally encapsulate the jointed electrical connectors 452 and conductive pads 442. Moreover, an encapsulant 460 may also be disposed on the backside redistribution structure 440, for encapsulating the top device dies 450 and components between the top device dies 450 and the backside redistribution structure 440.

In such three-dimensional semiconductor package 400, device dies are no longer limited to two-dimensional arrangement. As the device dies 450 are stacked over the device die 410, the device dies 450, 410 can be integrated in a more compact fashion.

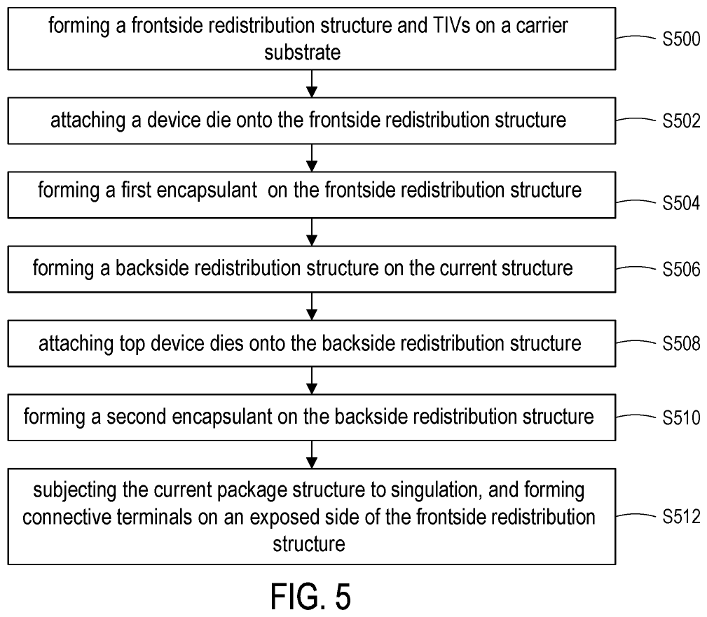

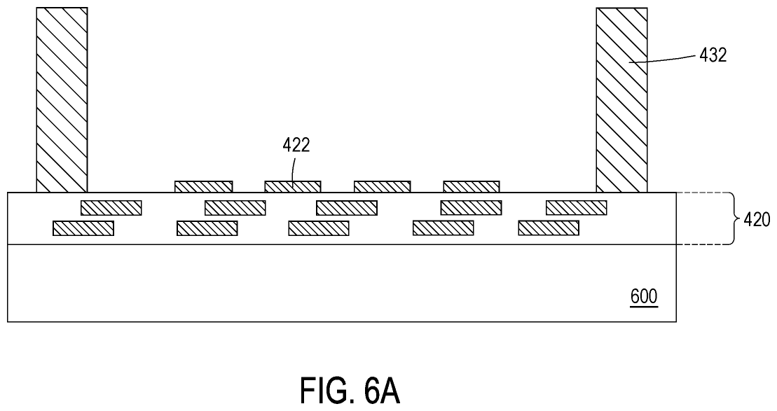

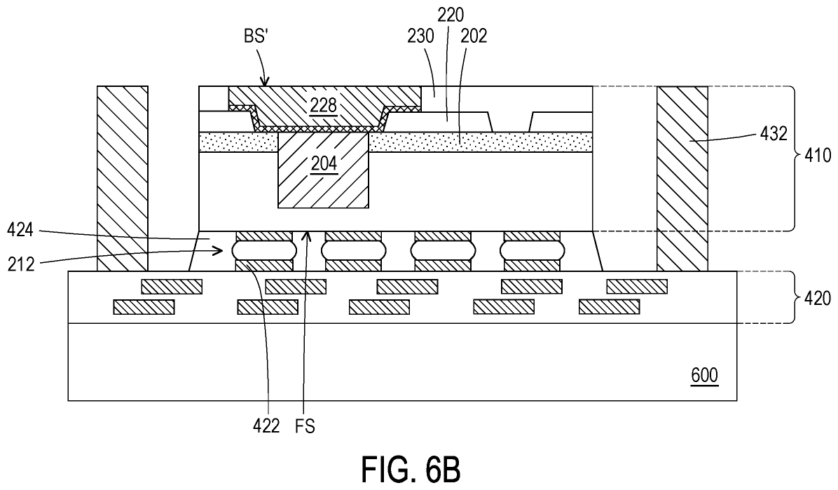

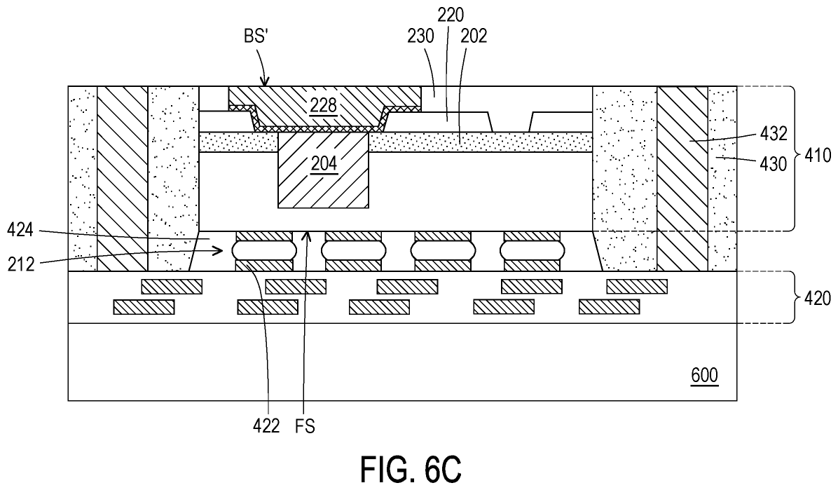

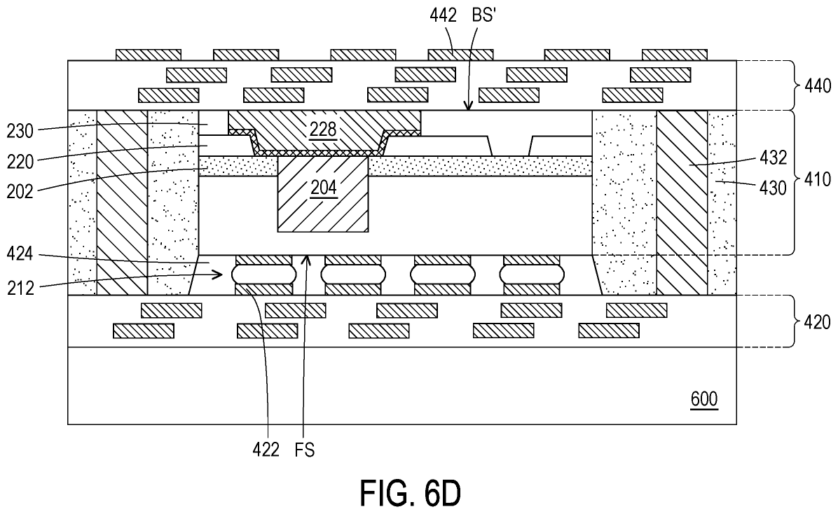

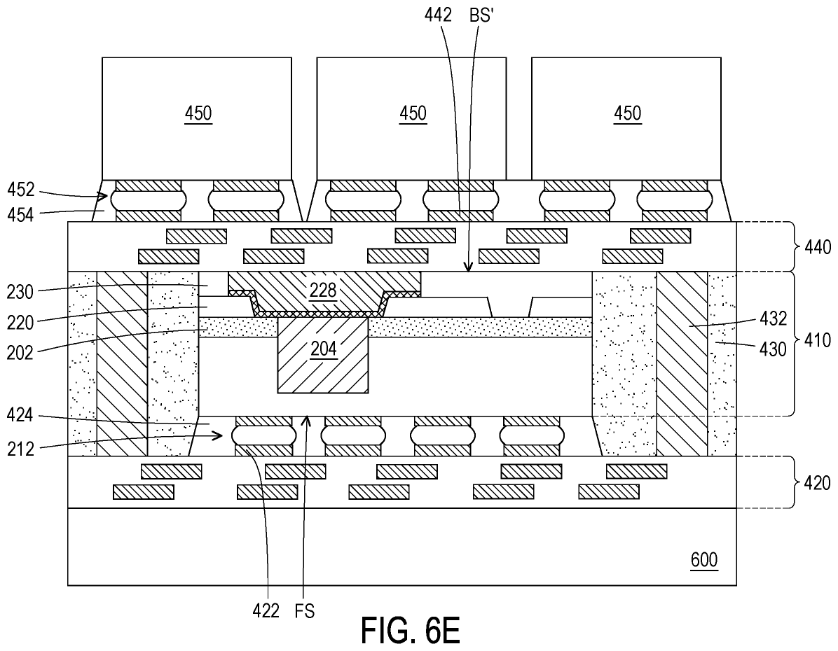

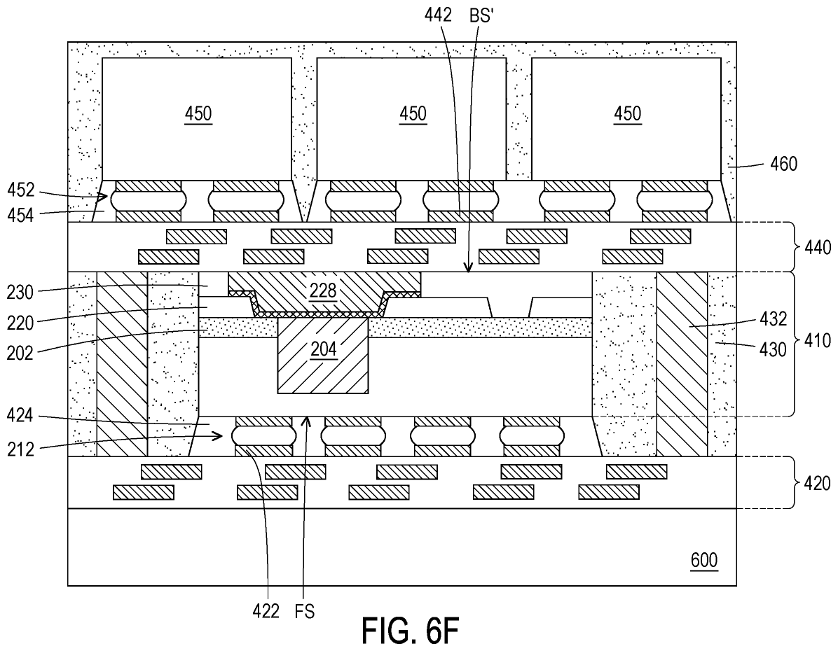

FIG. 5 is a flow diagram illustrating a method for forming the semiconductor package 400, according to some embodiments of the present disclosure. FIG. 6A through FIG. 6F are schematic cross-sectional views illustrating intermediate structures at various stages during the process shown in FIG. 5.

Referring to FIG. 5 and FIG. 6A, at a step S500, the frontside redistribution structure 420 and the TIVs 432 are formed on a carrier substrate 600. Specifically, the frontside redistribution structure 420 may be formed along a top surface of the carrier substrate 600. Thereafter, the TIVs 432 are formed on top of the frontside redistribution structure 420.

Referring to FIG. 5 and FIG. 6B, at a step S502, the device die 410 is attached onto the frontside redistribution structure 420. Although not shown, a singulation process is preliminarily performed on the device wafer 200′ shown in FIG. 2H, to obtain the device die 410. Thereafter, the device die 410 is attached onto the frontside redistribution structure 420 by its front side FS. The electrical connectors 424 exposed at the front side FS of the device die 410 are jointed to the conductive pads 422 exposed on the frontside redistribution structure 420, respectively. Upon the attachment, the underfill 424 may be provided in between the device die 410 and the frontside redistribution structure 420, to encapsulate the jointed electrical connectors 424 and conductive pads 422.

Referring to FIG. 5 and FIG. 6C, at a step S504, the encapsulant 430 is formed on the frontside redistribution structure 420. As a result, the device die 410 and the TIVs 432 are laterally encapsulated by the encapsulant 430, and the underfill 424 is in lateral contact with the encapsulant 430. According to the described embodiments, the TIVs 432 are formed before formation of the encapsulant 430. In alternative embodiments, the TIVs 432 may be formed after formation of the encapsulant 430. In these alternative embodiments, through holes may be formed through the encapsulant 430, and a conductive material may be provided to fill out the through holes for forming the TIVs 432.

Referring to FIG. 5 and FIG. 6D, at a step S506, the backside redistribution structure 440 is formed on the current structure. Accordingly, the backside redistribution structure 440 covers the back side BS' of the device die 410 as well as top surfaces of the encapsulant 430 and the TIVs 432.

Referring to FIG. 5 and FIG. 6E, at a step S508, the top device dies 450 are attached onto the backside redistribution structure 440. The electrical connectors 452 exposed at the bonding sides of the top device dies 450 are jointed to the conductive pads 442 exposed on the backside redistribution structure 440, respectively. Upon the attachment, the underfill(s) 454 may be provided in between the top device die 450 and the backside redistribution structure 440, to encapsulate the jointed electrical connectors 452 and conductive pads 442.

Referring to FIG. 5 and FIG. 6F, at a step S510, the encapsulant 460 is formed on the backside redistribution structure 440. As a result, the top device dies 450 are respectively encapsulated by the encapsulant 460, and the underfill(s) 454 are in lateral contact with the encapsulant 460. In some embodiments, the top device dies 450 are over-molded by the encapsulant 460.

Thereafter, at a step S512, current package structure is subjected to singulation after being detached from the carrier substrate 600, and the connective terminals 426 are formed on an exposed side of the frontside redistribution structure 420. Up to here, the semiconductor package 400 as shown in FIG. 4 has been formed.

As described, the device die 410 can be included in the semiconductor package 400. However, it should be appreciated that, the device die 410 is not limited to be applied in any certain type of three-dimensional semiconductor package. Other three-dimensional semiconductor packages that require TSVs and backside contact features should be applicable to the device die 410.

Further, as will be described in greater details, the backside contact features 238 can be accurately positioned by an alternative approach.

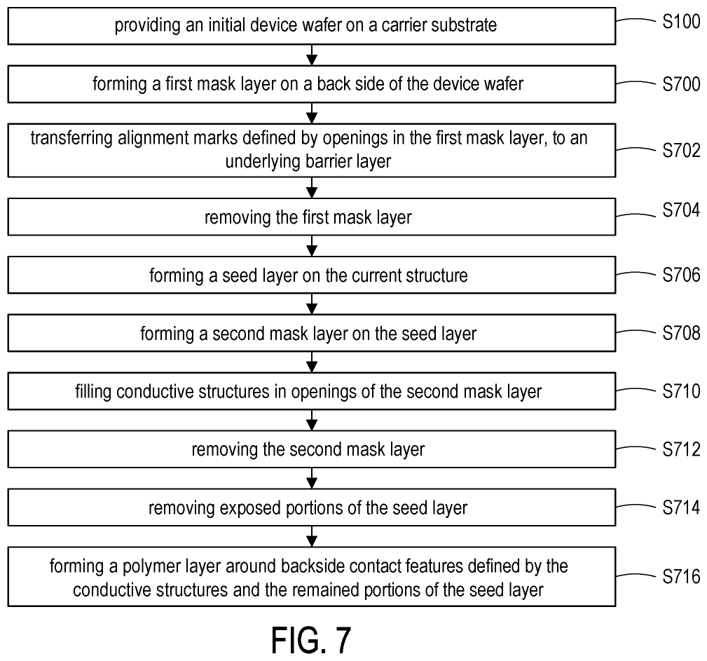

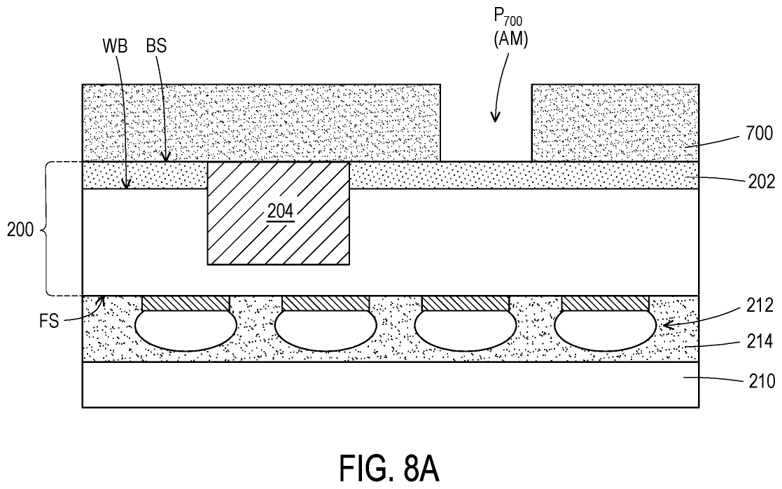

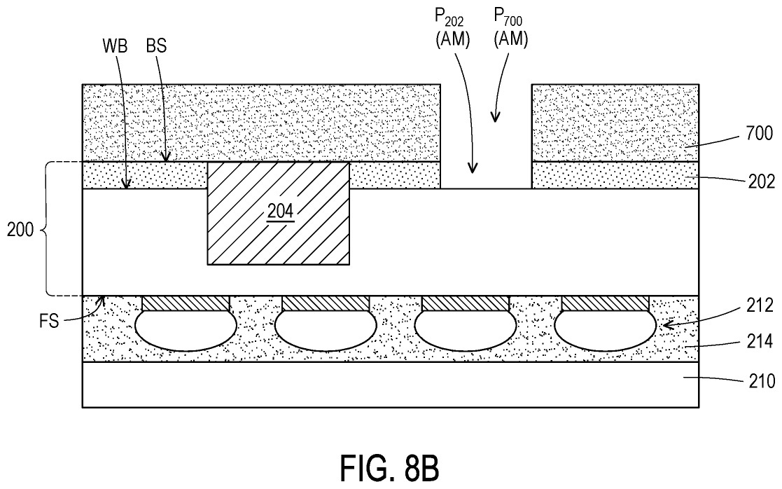

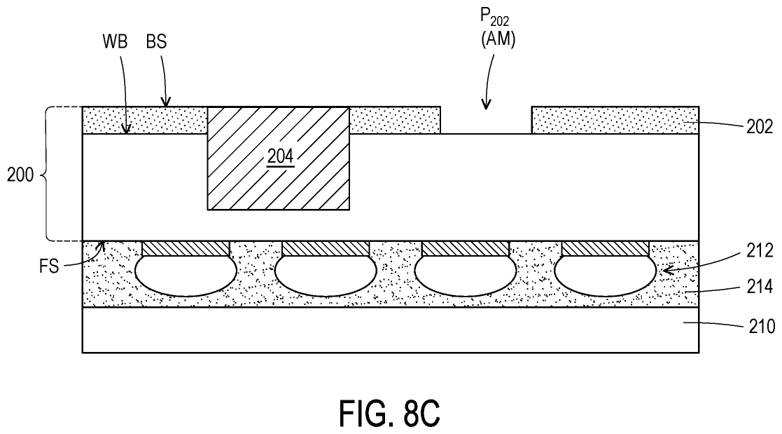

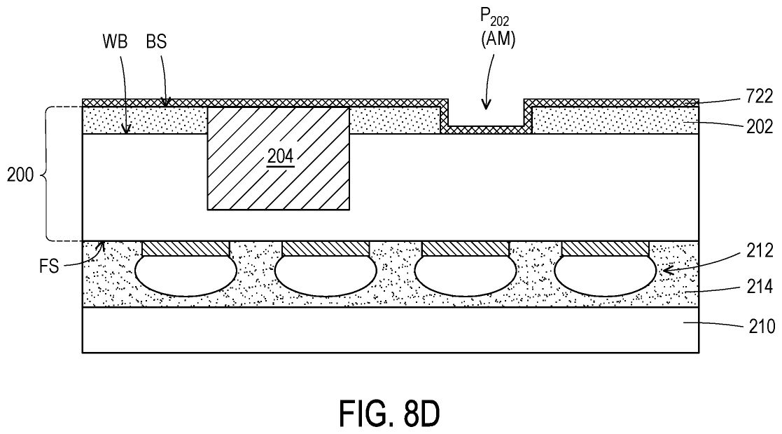

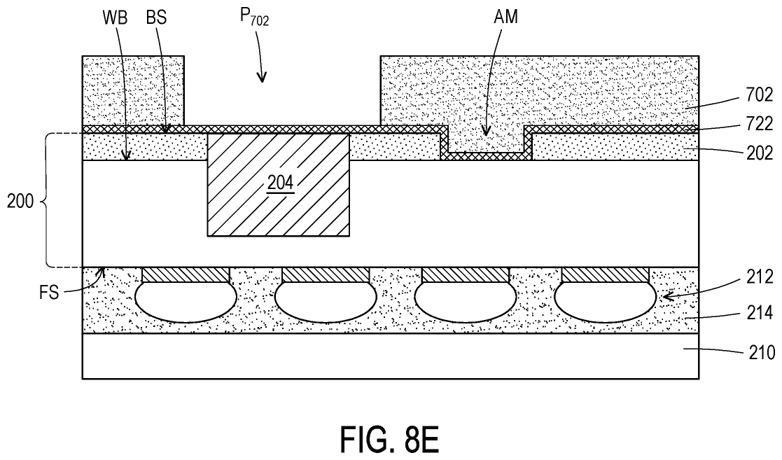

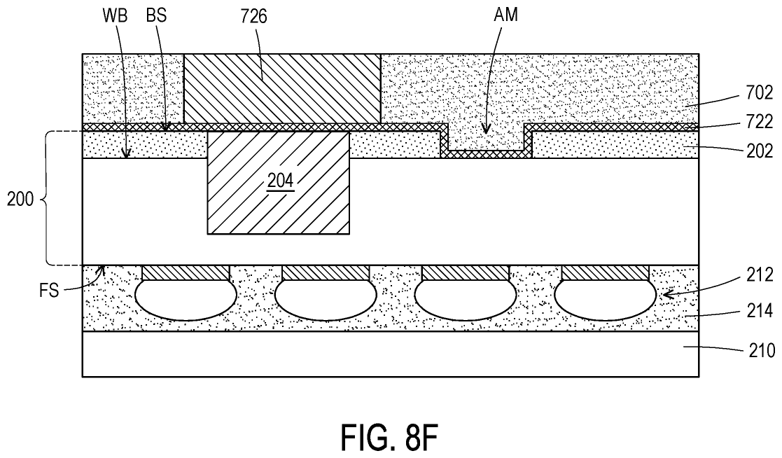

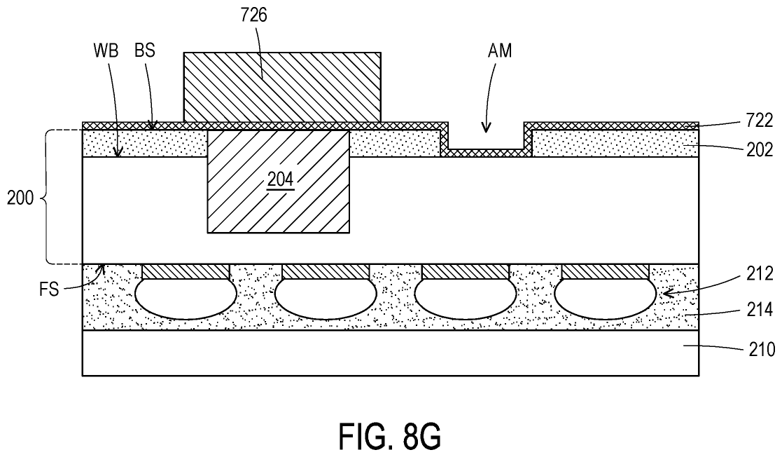

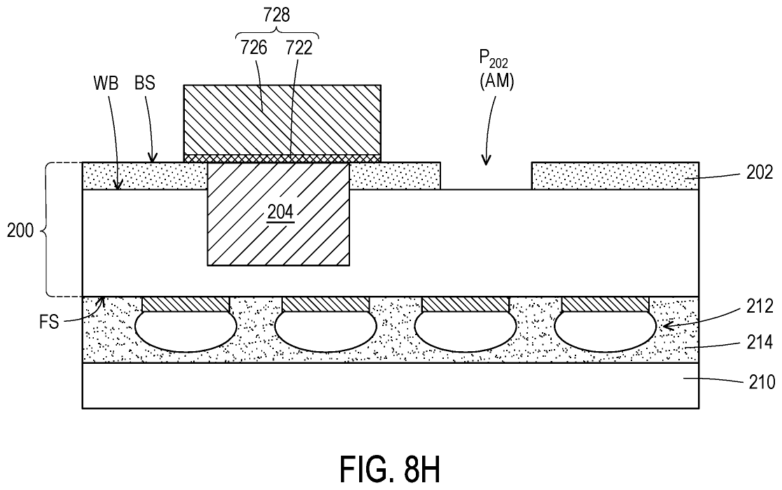

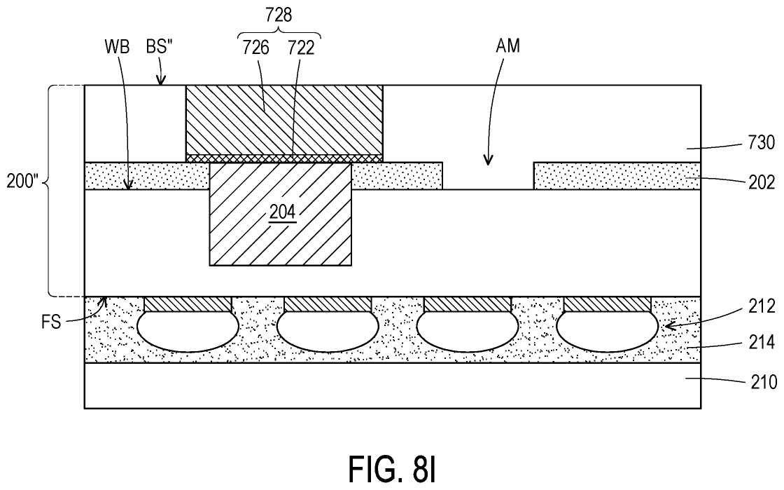

FIG. 7 is a flow diagram illustrating a method for forming backside contact features on a back side of a semiconductor die (in wafer form), according to some embodiments of the present disclosure. FIG. 8A through FIG. 8I are schematic cross-sectional views illustrating intermediate structures at various stages during the process flow shown in FIG. 7.

As similar to the process described with reference to FIG. 1, the process shown in FIG. 7 begins from the step S100 of providing an initial device wafer 200 on a carrier substrate 210. Subsequently, at a step S700, a mask layer 700 is formed on the back side BS of the device wafer 200. Openings P₇₀₀ (only a single one is shown) in the mask layer 700 define alignment marks AM to be transferred to the underlying barrier layer 202 in a subsequent step. In terms of geometry and dimension, these alignment marks AM may be each substantially identical with one of the alignment marks AM shown in FIG. 3 (e.g., one of the alignment marks AM1 to AM8). In addition, as similar to the arrangement of the alignment marks AM shown in FIG. 3, the alignment marks AM each defined by a group of the openings P₇₀₀ may be arranged within a region aside the TSVs 204. In some embodiments, the mask layer 700 is a photoresist layer. In these embodiments, the openings P₇₀₀ are formed by performing a lithography process on the mask layer 700.

Referring to FIG. 7 and FIG. 8B, at a step S702, the alignment marks AM defined by the openings P₇₀₀ in the mask layer 700 are transferred to the underlying barrier layer 202. Specifically, an etching process may be performed by using the mask layer 700 as a shadow mask. Portions of the barrier layer 202 exposed by the openings P₇₀₀ are etched, while other portions of the barrier layer 202 shielded by the mask layer 700 may not be subjected to removal. As a result, the alignment marks AM defined by the openings P₇₀₀ are transferred to openings P₂₀₂ (only a single one is shown) of the barrier layer 202. In some embodiments, the etching process is performed until exposure of the back surface WB of the semiconductor substrate. In these embodiments, the openings P₂₀₂ extend through the barrier layer 202, and regions of the back surface WB of the semiconductor substrate overlapped with the openings P₂₀₂ are currently exposed. In addition, a depth of the openings P₂₀₂ may be substantially identical with a thickness of the barrier layer 202. Furthermore, as being formed by an etching process (e.g., an anisotropic etching process), the openings P₂₀₂ defining the alignment marks AM may have substantially vertical sidewalls.

Referring to FIG. 7 and FIG. 8C, at a step S704, the mask layer 700 is removed. As a result, the barrier layer 202 and the TSVs 204 are currently exposed as well. In those embodiments where the mask layer 700 is a photoresist layer, the mask layer 700 may be removed by using a stripping process or an ashing process.

Referring to FIG. 7 and FIG. 8D, at a step S706, a seed layer 722 is formed on the current structure. Specifically, the seed layer 722 may conformally cover exposed surfaces of the TSVs 204, the barrier layer 202 and the semiconductor substrate. That is, the alignment marks AM defined by the openings P₂₀₂ of the barrier layer 202 are currently covered by the seed layer 722. Owing to conformity of the seed layer 722, the seed layer 722 is recessed at the openings P₂₀₂ of the barrier layer 202 that define the alignment marks AM. In this way, the alignment marks AM are currently defined by the recesses of the seed layer 722. In some embodiments, the seed layer 722 is a single layer, such as a copper layer. In other embodiments, the seed layer 722 is a multilayer structure including, for example, a titanium layer and a copper layer on top of the titanium layer.

Referring to FIG. 7 and FIG. 8E, at a step S708, a mask layer 702 is formed on the seed layer 722. The mask layer 702 may be a photoresist layer, and a lithography process may be performed on the mask layer 702 to form openings P₇₀₂ (only a single one is shown) through the mask layer 702. The openings P₇₀₂ respectively overlap one of the TSVs 204 and expose a portion of the seed layer 722 covering this TSV 204. During the lithography process, the alignment marks AM now defined by the recesses of the seed layer 722 can facilitate accurate positioning of the openings P₇₀₂. Although the alignment marks AM are covered by the mask layer 702, the seed layer 722 defining the alignment marks AM can reflect incident light through the mask layer 224. In this way, clear contrast along boundaries of the alignment marks AM is visible on an exposure tool, and can be used for accurately positioning the openings P₇₀₂.

Referring to FIG. 7 and FIG. 8F, at a step S710, conductive structures 726 (only a single one is shown) are filled into the openings P₇₀₂. Specifically, the conductive structures 726 are formed as conductive pads laterally spanning on the exposed portions of the seed layer 722. According to some embodiments, a plating process is used for forming a conductive material from the portions of the seed layer 722 exposed in the openings P₇₀₂, and a planarization process may be performed to remove excessive portions of the conductive material over the mask layer 702. Portions of the conductive material in the openings P₇₀₂ remain to form the conductive structures 726.

Referring to FIG. 7 and FIG. 8G, at a step S712, the mask layer 702 is removed. Upon removal of the mask layer 702, portions of the seed layer 722 not covered by the conductive structures 726 are exposed. In those embodiments where the mask layer 702 is a photoresist layer, the mask layer 702 may be removed by a stripping process or an ashing process.

Referring to FIG. 7 and FIG. 8H, at a step S714, the exposed portions of the seed layer 726 are removed. Remained portions of the seed layer 722 and the overlying conductive features 726 form backside contact features 728, for connecting the TSVs 204 to external conductive features. Upon patterning of the seed layer 722, portions of the barrier layer 202 around the backside contact features 728 are exposed, and portions of the semiconductor substrate overlapped with the openings P₂₀₂ for defining the alignment marks AM are exposed as well.

Referring to FIG. 7 and FIG. 8I, at a step S716, a polymer layer 730 is formed around the backside contact features 728. As a result, the exposed portions of the barrier layer 202 are covered by the polymer layer 730, and the openings P₂₀₂ for defining the alignment marks AM are filled up by the polymer layer 730. In some embodiments, top surfaces of the backside contact features 728 are substantially coplanar with a top surface of the polymer layer 730.

Up to here, the initial device wafer 200 has been processed to form a device wafer 200″ with the patterned barrier layer 202, the backside contact features 728 and the polymer layer 730. As identical with the initial device wafer 200, the device wafer 200″ also has the front side FS deployed with the electrical connectors 212. On the other hand, the device wafer 200″ may have a back side BS″ collectively defined by the top surfaces of the backside contact features 728 and the top surface of the polymer layer 730.

As similar to the device wafer 200′ described with reference to FIG. 2H, the device wafer 200″ may also be detached from the carrier substrate 210, and subjected to a packaging process identical or similar to the packaging process described with reference to FIG. 5 and FIG. 6A through FIG. 6F, to form a three-dimensional semiconductor package.

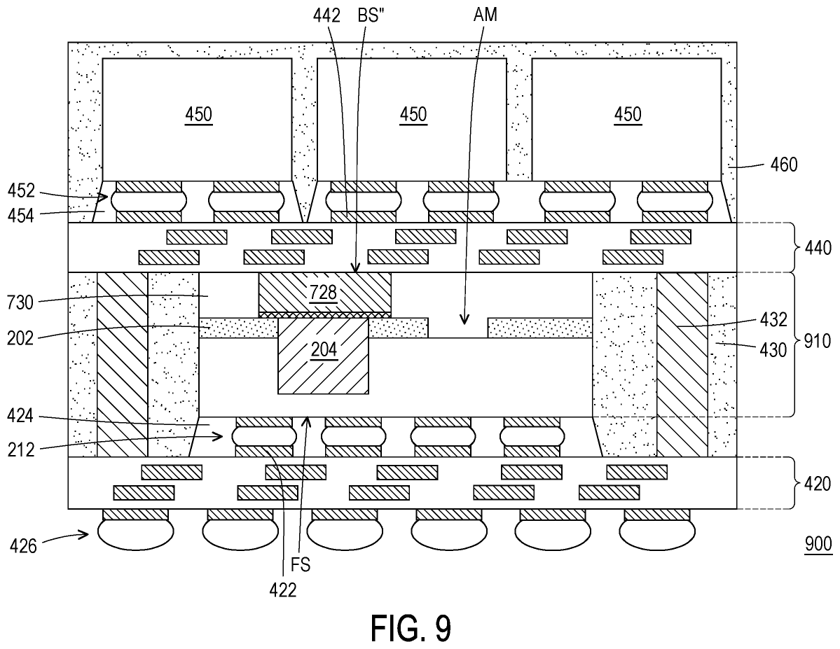

FIG. 9 is a schematic cross-sectional view illustrating a semiconductor package 900 including a device die 910 singulated from the device wafer 200″ shown in FIG. 8I, according to some embodiments of the present disclosure.

The semiconductor package 900 is similar to the semiconductor package 400 described with reference to FIG. 4. Specifically, the semiconductor package 900 can be resulted if the device die 410 in the semiconductor package 400 is replaced by a device die 910 singulated from the device wafer 200″ shown in FIG. 8I. The device die 910 in the semiconductor package 900 also includes the alignment marks AM used for accurately positioning the backside contact features 228. As a difference from the device die 410 shown in FIG. 4, the alignment marks AM in the device die 910 are defined in the barrier layer 202.

In regarding manufacturing, the semiconductor package 900 can be obtained by subjecting the device die 910 to a series of packaging process described with reference to FIG. 7 and FIG. 8A through FIG. 8I. However, it should be appreciated that, the device die 910 is not limited to be applied in any certain type of three-dimensional semiconductor package. Other three-dimensional semiconductor packages that require TSVs and backside contact features should be applicable to the device die 910.

As described, the alignment marks AM in the device die 910 are resulted from the openings P₂₀₂ formed through the barrier layer 202. As additional alternatives, the alignment marks AM are defined by shallower or deeper openings.

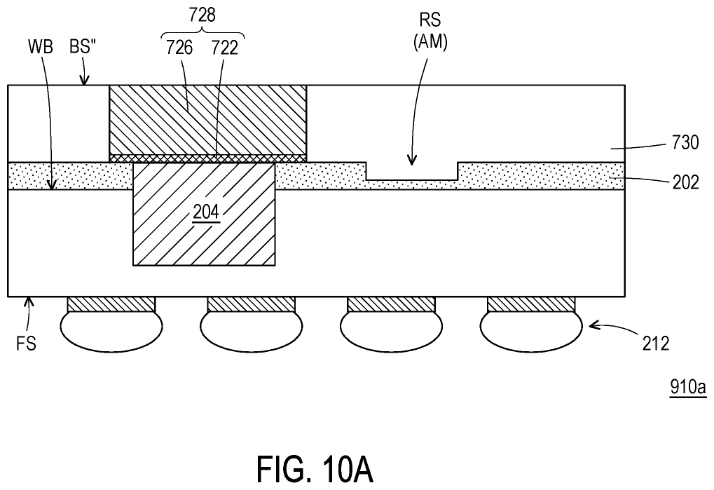

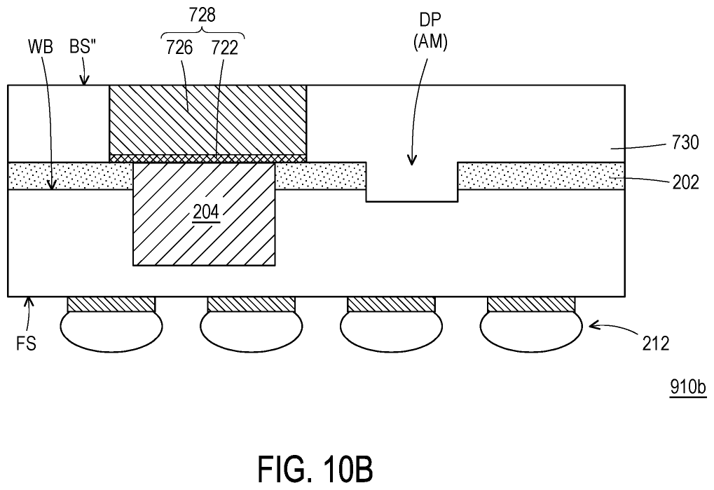

FIG. 10A is a schematic cross-sectional view illustrating a device die 910a, according to some embodiments of the present disclosure.

The device die 910a is similar to the device die 910 shown in FIG. 9, except that the alignment marks AM included in the device die 910a are defined by recesses RS (only a single one is shown) at a top surface of the barrier layer 202. A process for forming the device die 910a is similar to the process described with reference to FIG. 7 and FIG. 8A through FIG. 8I, except for a few differences. At the step shown in FIG. 8B, the barrier layer 202 is not etched through, and the back surface WB of the semiconductor substrate is not exposed. In other words, the etching process performed on the barrier layer 202 is stopped before exposure of the back surface WB of the semiconductor substrate. As a result, the barrier layer 202 is patterned with the recesses RS, rather than the openings P₂₀₂ shown in FIG. 8B. In a subsequent step, the recesses RS are covered by the seed layer 722, and the seed layer 722 is recessed in corresponding to the recesses RS, due to its conformity. At the step shown in FIG. 8E, the alignment marks AM now defined by the recesses of the seed layer 722 can facilitate accurate positioning of the openings P 702 formed in the mask layer 702 during a lithography process, as clear contrast along boundaries of the alignment marks AM is visible on an exposure tool. Thereafter, the recesses RS are exposed upon patterning of the seed layer 722, and then filled by the polymer layer 730.

The device die 910a may be subjected to a series of packaging process described with reference to FIG. 7 and FIG. 8A through FIG. 8I, to form a semiconductor package similar to the semiconductor package 400 shown in FIG. 4 or the semiconductor package 900 shown in FIG. 9. However, it should be appreciated that, the device die 910a is not limited to be applied in any certain type of three-dimensional semiconductor package. Other three-dimensional semiconductor packages that require TSVs and backside contact features should be applicable to the device die 910a.

FIG. 10B is a schematic cross-sectional view illustrating a device die 910b, according to some embodiments of the present disclosure.

The device die 910b is similar to the device die 910 shown in FIG. 9, except that the alignment marks AM included in the device die 910b are defined by deep openings DP formed through the barrier layer 202 and extending into the semiconductor substrate from the back surface WB of the semiconductor substrate. A process for forming the device die 910b is similar to the process described with reference to FIG. 7 and FIG. 8A through FIG. 8I, except for a few differences. At the step shown in FIG. 8B, the barrier layer 202 is etched through, and portions of the semiconductor substrate overlapped with the openings P₇₀₀ are recessed from the back surface WB of the semiconductor substrate. In other words, the etching process performed on the barrier layer 202 is stopped after exposure of the back surface WB of the semiconductor substrate, and the deep openings DP penetrating through the barrier layer 202 and extending into the semiconductor substrate are resulted. In a subsequent step, the deep openings DP are covered by the seed layer 722, and the seed layer 722 is recessed in corresponding to the deep openings DP, due to its conformity. At the step shown in FIG. 8E, the alignment marks AM now defined by the recesses of the seed layer 722 can facilitate accurate positioning of the openings P₇₀₂ formed in the mask layer 702 during a lithography process, as clear contrast along boundaries of the alignment marks AM is visible on an exposure tool. Thereafter, the deep openings DP are exposed upon patterning of the seed layer 722, and then filled by the polymer layer 730. In these embodiments, the polymer layer 730 may further extend into the semiconductor substrate.

The device die 910b may be subjected to a series of packaging process described with reference to FIG. 7 and FIG. 8A through FIG. 8I, to form a semiconductor package similar to the semiconductor package 400 shown in FIG. 4 or the semiconductor package 900 shown in FIG. 9. However, it should be appreciated that, the device die 910b is not limited to be applied in any certain type of three-dimensional semiconductor package. Other three-dimensional semiconductor packages that require TSVs and backside contact features should be applicable to the device die 910b.

As above, solutions for accurately positioning backside contact features on TSVs and resulted structures are provided. According to some embodiments, an additional polymer layer (i.e., the polymer layer 220) lying on a barrier layer along chip back side is used for defining alignment marks for facilitating accurate positioning of the backside contact features. In these embodiments, the alignment marks are resulted from openings in the additional polymer layer, and the backside contact features may respectively include a via portion surrounded by the additional polymer layer, and a pad portion lying over the additional polymer layer. Moreover, by further disposing such additional polymer layer, stress in a redistribution structure formed thereon can be reduced, and cracking of conductive features in such redistribution structure can be effectively avoided. In alternative embodiments, alignment marks are defined by openings formed through the barrier layer or recesses at a top surface of the barrier layer. In these alternative embodiments, the additional polymer layer is not required, and a polymer layer surrounding the backside contact features may fill out the alignment marks and in direct contact with the barrier layer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a method for forming a semiconductor package is provided. The method comprises: providing a device wafer, with a barrier layer covering a back surface of a semiconductor substrate, and having a through substrate via penetrating through the barrier layer and extending into the semiconductor substrate; defining an alignment mark over the back surface of the semiconductor substrate and laterally spaced apart from the through substrate via; forming a seed layer over the back surface of the semiconductor substrate, wherein the seed layer covers the through substrate via and the alignment mark, and has a recess portion corresponding to the alignment mark; forming a mask layer on the seed layer; performing a lithography process on the mask layer by using a redefined alignment mark formed by the recess portion of the seed layer, to form an opening through the mask layer and overlapping the through substrate via; filling a conductive structure in the opening; removing the mask layer and portions of the seed layer around the conductive structure; and singulating the processed device wafer.

In another aspect of the present disclosure, a semiconductor package is provided. The semiconductor package comprises: a first device die and a second device die vertically spaced apart from the first device die. The first device die comprises: a barrier layer, covering a back surface of a semiconductor substrate; a through substrate via, penetrating through the barrier layer and extending into the semiconductor substrate; a first polymer layer, stacked on the barrier layer and having at least one opening defining an alignment mark aside the through substrate via; a second polymer layer, disposed on the first polymer layer, and protruding into and filling out the at least one opening defining the alignment mark; and a backside contact feature, extending through the first and second polymer layers, to reach the through substrate via. The second device die is communicated with the first device die through the backside contact feature.

In yet another aspect of the present disclosure, a semiconductor package is provided. The semiconductor package comprises: a device die and a backside redistribution structure on top of the device die. The device die comprises: a barrier layer, covering a back surface of a semiconductor substrate, wherein at least one concave extends into the barrier layer for defining an alignment mark; a through substrate via, penetrating through the barrier layer and extending into the semiconductor substrate, wherein the alignment mark is located aside the through substrate via; a polymer layer, disposed on the barrier layer and the through substrate via, and protrudes into and fills out the at least one concave defining the alignment mark; and a backside contact feature, extending through the polymer layer to establish contact with the through substrate via. The backside redistribution structure is disposed along top surfaces of the polymer layer and the backside contact feature, and conductive features in the backside redistribution structure are electrically connected to the backside contact feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor package, comprising:
providing a device wafer, with a barrier layer covering a back surface of a semiconductor substrate, and having a through substrate via penetrating through the barrier layer and extending into the semiconductor substrate;
defining an alignment mark over the back surface of the semiconductor substrate and laterally spaced apart from the through substrate via;
forming a seed layer over the back surface of the semiconductor substrate, wherein the seed layer covers the through substrate via and the alignment mark, and has a recess portion corresponding to the alignment mark;
forming a mask layer on the seed layer;
performing a lithography process on the mask layer by using a redefined alignment mark formed by the recess portion of the seed layer, to form an opening through the mask layer and overlapping the through substrate via;
filling a conductive structure in the opening;
removing the mask layer and portions of the seed layer around the conductive structure; and
singulating the processed device wafer.

2. The method for forming the semiconductor package according to claim 1, wherein the alignment mark remains in a device die singulated from the processed device wafer.

3. The method for forming the semiconductor package according to claim 1, wherein defining the alignment mark comprises:
forming a first polymer layer on the barrier layer; and
forming a first opening and at least one second opening through the first polymer layer, wherein the first opening exposes the through substrate via, and the at least one second opening exposes the barrier layer and define the alignment mark.

4. The method for forming the semiconductor package according to claim 3, wherein the seed layer conformally covers a surface defined by the first polymer layer and portions of the through substrate via and the barrier layer exposed by the first opening and the at least one second opening of the first polymer layer.

5. The method for forming the semiconductor package according to claim 3, wherein the at least one second opening of the polymer layer is filled up by the mask layer before removal of the mask layer.

6. The method for forming the semiconductor package according to claim 3, wherein the conductive structure is also filled in the first opening of the first polymer layer.

7. The method for forming the semiconductor package according to claim 3, further comprising:
forming a second polymer layer on the first polymer layer after removal of the mask layer and the portions of the seed layer around the conductive structure, wherein the second polymer layer protrudes into and fills out the at least one second opening of the first polymer layer.

8. The method for forming the semiconductor package according to claim 7, wherein a backside contact feature formed by the conductive structure and a remained portion of the seed layer has a via portion filling in the first opening of the first polymer layer, and has a pad portion spanning on the first polymer layer and laterally surrounded by the second polymer layer.

9. The method for forming the semiconductor package according to claim 1, wherein defining the alignment mark comprises:
forming a patterned mask layer on the barrier layer and the through substrate via;
performing an etching process by using the patterned mask layer as a mask, to form at least one concave into the barrier layer for defining the alignment mark; and
removing the patterned mask layer.

10. The method for forming the semiconductor package according to claim 9, wherein the at least one concave is at least one opening extending through the barrier layer.

11. The method for forming the semiconductor package according to claim 10, wherein the at least one concave further extends into the semiconductor substrate.

12. The method for forming the semiconductor package according to claim 9, wherein the at least one concave is at least one recess at a top surface of the barrier layer.

13. The method for forming the semiconductor package according to claim 9, the seed layer extends into the at least one concave upon formation, and the mask layer fills out the at least one concave before removal of the mask layer.

14. The method for forming the semiconductor package according to claim 9, further comprising:
forming a polymer layer on the barrier layer, wherein the polymer layer protrudes into and fills out the at least one concave, and laterally surrounds a backside contact feature formed by the conductive structure and a remained portion of the seed layer.

15. A semiconductor package, comprising:
a first device die, comprising:
a barrier layer, covering a back surface of a semiconductor substrate;
a through substrate via, penetrating through the barrier layer and extending into the semiconductor substrate;
a first polymer layer, stacked on the barrier layer and having at least one opening defining an alignment mark aside the through substrate via;
a second polymer layer, disposed on the first polymer layer, and protruding into and filling out the at least one opening defining the alignment mark; and
a backside contact feature, extending through the first and second polymer layers, to reach the through substrate via; and
a second device die, vertically spaced apart from the first device die, and communicated with the first device die through the backside contact feature.

16. The semiconductor package according to claim 15, wherein the backside contact feature has a via portion laterally surrounded by the first polymer layer, and has a pad portion spanning on the first polymer layer and laterally surrounded by the second polymer layer.

17. The semiconductor package according to claim 15, wherein a top surface of the backside contact feature is substantially coplanar with a top surface of the second polymer layer.

18. A semiconductor package, comprising:
a device die, comprising:
a barrier layer, covering a back surface of a semiconductor substrate, wherein at least one concave extends into the barrier layer for defining an alignment mark;
a through substrate via, penetrating through the barrier layer and extending into the semiconductor substrate, wherein the alignment mark is located aside the through substrate via;
a polymer layer, disposed on the barrier layer and the through substrate via, and protrudes into and fills out the at least one concave defining the alignment mark; and
a backside contact feature, extending through the polymer layer to establish contact with the through substrate via; and
a backside redistribution structure, disposed along a top surface of the polymer layer and a top surface of the backside contact feature, wherein conductive features in the backside redistribution structure are electrically connected to the backside contact feature.

19. The semiconductor package according to claim 18, wherein the at least one concave penetrates through the barrier layer, or penetrates through the barrier layer and further extends into the semiconductor substrate.

20. The semiconductor package according to claim 18, wherein the at least one concave is at least one recess at a top surface of the barrier layer, which does not penetrate through the barrier layer.
